(19) United States
(12) Patent Application Publication
(10) Pub. No.: US 2013/0209776 A1
(43) Pub. Date: Aug. 15, 2013

(54) BACK SHEET OF A SOLAR CELL MODULE FOR PHOTOVOLTAIC POWER GENERATION

(71) Applicant: Min-Hyuk Kim, Gunpo-si (KR)

(72) Inventor: Min-Hyuk Kim, Gunpo-si (KR)

(21) Appl. No.: 13/879,257

(22) PCT Filed: Sep. 30, 2011
(86) PCT No.: PCT/KR2011/007211

§ 371 Date: Apr. 12, 2013

(30) Foreign Application Priority Data
Oct. 13, 2010 (KR) 10-2010-0099992
Dec. 9, 2010 (KR) 10-2010-0125755
May 6, 2011 (KR) 10-2011-0043049
May 6, 2011 (KR) 10-2011-0043050

(51) Int. Cl. H01L 31/048; B32B 9/04; B32B 9/00; B32B 27/08; B32B 15/08

(52) U.S. Cl. CPC H01L 31/0487; B32B 27/08; B32B 15/08; B32B 9/005; B32B 9/045; B32B 9/007
USPC 428/220; 428/522; 428/483; 428/473.5; 428/518; 428/421; 428/463; 428/423.7; 428/424.8; 428/425.8; 428/446; 428/451; 428/408

(57) ABSTRACT

Disclosed is a back sheet for a solar cell module for photovoltaic power generation, including a first resin layer attached to EVA under a solar cell, a heat conductive layer formed on the lower surface of the first resin layer, a lower layer formed on the lower surface of the heat conductive layer, and an adhesive layer formed between the first resin layer and the heat conductive layer, wherein the lower layer is a heat conductive coating layer using an inorganic coating or organic-inorganic hybrid coating, or a second resin layer. The back sheet of the invention includes the first resin layer, the adhesive layer, the metallic heat conductive layer, the lower layer and the adhesive layer, thus increasing a withstanding voltage and ensuring an insulation thickness by virtue of the first resin layer, thereby improving insulation performance, wherein the heat conductive coating layer introduced as the lower layer exhibits high heat conductivity, emissivity and reflectivity to obtain high heat dissipation performance, thereby increasing the power generation of the solar cell module, or wherein the second resin layer introduced as the lower layer increases a withstanding voltage and ensures an insulation thickness, thereby enhancing insulation performance and preventing the heat conductive layer from warping due to differences in coefficient of thermal expansion and cooling rate between the adhesive layer and the heat conductive layer, and also wherein the production cost is decreased to thus increase profitability and productivity is raised by 30% or more compared to conventional solar cell modules.

### TECHNICAL FIELD

The present invention relates to a back sheet for a solar cell module for photovoltaic power generation, which comprises a first resin layer, an adhesive layer, a metallic heat conductive layer, a lower layer and an adhesive layer, thus increasing a withstanding voltage and ensuring an insulation thickness by virtue of the first resin layer, thereby improving insulation performance, wherein a heat conductive coating layer is introduced as the lower layer to exhibit high heat conductivity, emissivity and reflectivity so as to obtain high heat dissipation performance, thereby increasing the power generation of the solar cell module, or wherein a second resin layer is introduced as the lower layer to increase a withstanding voltage and ensure an insulation thickness, thereby enhancing insulation performance and preventing the heat conductive layer from warping due to differences in coefficient of thermal expansion and cooling rate between the adhesive layer and the heat conductive layer, and also wherein the production cost is decreased to thus increase profitability and productivity is raised by 30% or more compared to conventional solar cell modules.

### BACKGROUND ART

Generally, photovoltaic (PV) cells directly convert incident solar light energy into electric energy. These PV cells use pollution-free unlimited solar light energy and thus obviate the need for fuel, and generate neither air pollution nor waste and are thus eco-friendly. Furthermore, because these cells are semiconductor devices, they generate little mechanical vibration or noise.

Recently, as energy-related problems become more serious both domestically and internationally, PV cells are receiving increased attention and comprehensive research and development thereof is ongoing. Examples of conventional cells include PV cells in which solar light is directly incident on a multi-cell without reflection or refraction, or concentrating PV cells in which a reflector is provided in front of the multi-cell to concentrate solar light.

However, concentrating PV cells are problematic because power generation efficiency is not actually higher compared to

PV cells on which the solar light is directly incident. The reason is that the power generation efficiency of the concentrating PV cells is determined by multiplying the power output efficiency of the cell by transmittance or reflectivity.

Specifically, in the case of the above cell type, when the power conversion efficiency which is a ratio of incident solar light output to power generation output is about 15% and the transmittance or reflectivity is 90%, the power conversion efficiency of the concentrating PV cell is calculated by 15%×90% =13.5%, and thus the power conversion efficiency is not actually high.

Hence, in order to obtain high power conversion efficiency, a Fresnel lens is provided on the cell so that incident solar light is concentrated 500 times or more on the cell.

However, because the solar light concentrated 500-times is focused on a single cell, the temperature of the cell may drastically increase, undesirably lowering the power conversion efficiency.

Thus, with the goal of decreasing the drastically increased temperature of the cell, attempts have been made to provide a heat sink having a plurality of fins attached to a case which protects the cell externally, but such a heat sink is used to dissipate heat from the entire PV cell, and thus is insufficient in terms of decreasing the temperature of the above cell.

In addition, attempts have been made to provide a PV cell module and a holder which is made of an aluminum alloy and supports the PV cell module, wherein the holder includes a plurality of coolant paths for cooling the PV cell module.

Although the holder having the coolant paths, which is made of aluminum or aluminum alloy having high heat conductivity, is considered to sufficiently dissipate heat of the PV cell module, the holder made of aluminum or the cooling fins have a fine surface roughness and thus the PV cell module does not come into close contact with the heat dissipation member from the microscopic point of view. Hence, an air layer having low heat conductivity exists between the PV cell module and the heat dissipation member.

Even when the heat dissipation member is made of aluminum, copper, etc., having high heat conductivity, the air layer is present and thereby heat of the PV cell module is not sufficiently dissipated, undesirably lowering the energy conversion efficiency.

In regard to a conventional heat dissipation sheet or back sheet, Korean Patent No. 10-0962642 (Publication date: Jun. 11, 2010), entitled “PV module having heat dissipation sheet with ceramic coating,” discloses that a glass substrate, front solar EVA, a solar cell, back solar EVA, and a heat dissipation sheet having a ceramic coating layer are sequentially stacked, wherein the heat dissipation sheet is made of any one material having high heat conductivity selected from among aluminum, copper, brass, steel plates, stainless steel, and metal sheets having emissivity equal to or higher than that of the above materials. Furthermore, the ceramic coating layer which is heat conductive is formed on one or both surfaces of the heat dissipation sheet using a typical ceramic coating process, thereby increasing heat dissipation efficiency and ultimately raising the power generation efficiency of the module.

However, the heat dissipation sheet of the above conventional technique is laminated on the back solar EVA using heat and pressure. As such, in the course of cooling after application of heat and pressure, the heat dissipation sheet in a thin film form, that is, a metal film or a ceramic coating layer, and the back solar EVA are different in terms of the coefficient of thermal expansion and the cooling rate, undesirably warping or bending the PV module, which becomes unsuitable for use in various performance tests or fails to satisfy performance standards.

Also, the heat dissipation sheet of the above conventional technique is formed by coating the metal film with the ceramic coating layer, making it difficult to ensure a sufficient insulation thickness and deteriorating insulation performance. Thus, the above PV module has difficulty passing performance tests, such as Hi-pot tests for testing a withstanding voltage or insulation performance, and partial discharge pressure tests, and does not satisfy safety standards such as UL certification, undesirably making it difficult to manufacture actual products.

### DISCLOSURE

### Technical Problem

Accordingly, the present invention has been made keeping in mind the above problems occurring in the related art, and an object of the present invention is to provide a back sheet for a solar cell module for photovoltaic power generation, which may comprise a first resin layer, an adhesive layer, a metallic heat conductive layer, a lower layer and an adhesive layer, thus increasing a withstanding voltage and ensuring an insulation thickness by virtue of the first resin layer, thereby improving insulation performance, wherein a heat conductive coating layer may be introduced as the lower layer to exhibit high heat conductivity, emissivity and reflectivity so as to obtain high heat dissipation performance, thereby increasing the power generation of the solar cell module, or wherein a second resin layer may be introduced as the lower layer to increase a withstanding voltage and ensure an insulation thickness, thereby enhancing insulation performance and preventing the heat conductive layer from warping due to differences in coefficient of thermal expansion and cooling rate between the adhesive layer and the heat conductive layer, and also wherein the production cost is decreased to thus increase profitability and productivity is raised by 30% or more compared to conventional solar cell modules.

Another object of the present invention is to provide a back sheet for a solar cell module for photovoltaic power generation, wherein a heat conductive coating layer may be provided using an inorganic coating or an organic-inorganic hybrid coating, thus exhibiting superior insulation performance and heat dissipation performance, and high heat resistance and adhesive strength, and enabling thickness of the module, making it possible to manufacture compact products.

Still another object of the present invention is to provide a back sheet for a solar cell module for photovoltaic power generation, wherein a protective layer having high weather resistance and corrosion resistance may be provided on the lower surface of the heat conductive coating layer, thus blocking UV light, and improving surface protection performance and damp proofing performance, thereby upgrading the quality of products.

### Technical Solution

The present invention provides a back sheet for a solar cell module for photovoltaic power generation, comprising a first resin layer attached to EVA under a solar cell; a heat conductive layer formed on a lower surface of the first resin layer; a lower layer formed on a lower surface of the heat conductive layer; and an adhesive layer formed between the first resin layer and the heat conductive layer, wherein the first resin layer functions to increase a withstanding voltage and to ensure an insulation thickness, thus improving insulation performance.

In the present invention, the lower layer may be a heat conductive coating layer formed using an inorganic coating or an organic-inorganic hybrid coating.

In the present invention, the back sheet may further comprise a protective layer formed on a lower surface of the heat conductive coating layer to block UV light and to obtain surface protection performance and damp proofing performance.

In the present invention, the lower layer may be a second resin layer, the back sheet may further comprise an adhesive layer formed between the heat conductive layer and the second resin layer, wherein the second resin layer functions to increase a withstanding voltage and to ensure an insulation thickness, thus improving insulation performance, and either or both of the first resin layer and the second resin layer function to prevent the heat conductive layer from warping due to differences in coefficient of thermal expansion and cooling rate between the adhesive layer and the heat conductive layer.

In the present invention, the back sheet may further comprise a heat conductive coating layer formed on a lower surface of the second resin layer using an inorganic coating or an organic-inorganic hybrid coating.

In the present invention, the back sheet may further comprise a protective layer formed on a lower surface of the heat conductive coating layer to block UV light and to obtain surface protection performance and damp proofing performance.

In the present invention, the first resin layer may comprise any one material selected from among PET, PI, BOPP, OPP, PVF, PVDF, TPE, ETFE, and an aramid film.

In the present invention, the heat conductive layer may comprise any one metal material selected from among aluminum, copper, brass, a steel plate and stainless steel.

In the present invention, the adhesive layer may be an EVA-, acryl- or urethane-based clear adhesive film.

In the present invention, the second resin layer may comprise any one material selected from among PET, PI, BOPP, OPP, PVF, PVDF, TPE, ETFE and an aramid film.

In the present invention, the back sheet comprising the first resin layer, the heat conductive layer, the second resin layer and the adhesive layer may be formed to a thickness of 250˜750 μm.

In the present invention, the back sheet may further comprise a carbon black layer formed on one or both surfaces of the second resin layer using a carbon black resin.

In the present invention, the back sheet may further comprise a heat dissipation ceramic coating layer formed on one or both surfaces of the second resin layer.

### Advantageous Effects

According to the present invention, a back sheet for a solar cell module for photovoltaic power generation comprises a first resin layer, an adhesive layer, a metallic heat conductive layer, a lower layer and an adhesive layer, thus increasing a withstanding voltage and ensuring an insulation thickness by virtue of the first resin layer, thereby improving insulation performance. A heat conductive coating layer can be introduced as the lower layer to exhibit high heat conductivity, emissivity and reflectivity so as to obtain high heat dissipation performance, thereby increasing the power generation of the solar cell module, or a second resin layer can be introduced as the lower layer to increase a withstanding voltage and ensure an insulation thickness, thereby enhancing insulation performance and preventing the heat conductive layer from warping due to differences in coefficient of thermal expansion and cooling rate between the adhesive layer and the heat conductive layer. Also, the production cost can be decreased to thus increase profitability and productivity can be raised by 30% or more compared to conventional solar cell modules.

In addition, in the back sheet for a solar cell module for photovoltaic power generation, a heat conductive coating layer can be provided using an inorganic coating or an organic-inorganic hybrid coating, thus exhibiting superior insulation performance and heat dissipation performance, and high heat resistance and adhesive strength, and enabling thickness of the module, making it possible to manufacture compact products.

In addition, in the back sheet for a solar cell module for photovoltaic power generation, a protective layer having high weather resistance and corrosion resistance can be provided on the lower surface of the heat conductive coating layer, thus blocking UV light, and improving surface protection performance and damp proofing performance, thereby upgrading the quality of products.

### DESCRIPTION OF DRAWINGS

FIG. 1 is a cross-sectional view illustrating a back sheet for a solar cell module for photovoltaic power generation according to an embodiment of the present invention;

FIG. 2 is a cross-sectional view illustrating a back sheet for a solar cell module for photovoltaic power generation according to a modification of the embodiment of the present invention;

FIG. 3 is of cross-sectional views illustrating the back sheet for a solar cell module for photovoltaic power generation according to the present invention, including a protective layer; and

FIG. 4 is of cross-sectional views illustrating the back sheet for a solar cell module for photovoltaic power generation according to the present invention, including a carbon black layer and a heat dissipation ceramic coating layer.

### DESCRIPTION OF THE REFERENCE NUMERALS IN THE DRAWINGS

| | |
|---|---|
| SC: solar cell | G: glass |
| 10: first resin layer | 20: heat conductive layer |
| 30: second resin layer | 40: adhesive layer |

50: heat conductive coating layer
60: protective layer
70: carbon black layer
80: heat dissipation ceramic coating layer

### Mode for Invention

Hereinafter, a detailed description will be given of a back sheet for a solar cell module for photovoltaic power generation according to the present invention with reference to the appended drawings.

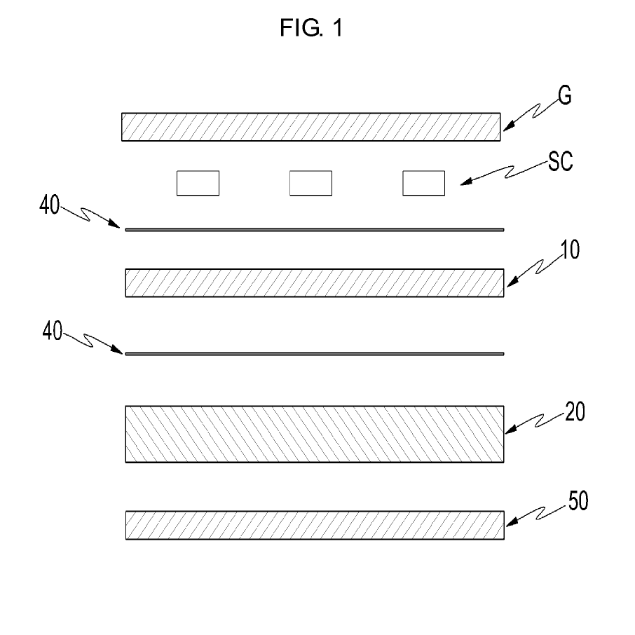

As illustrated in FIGS. 1 to 4, the back sheet for a solar cell module for photovoltaic power generation according to the present invention includes a first resin layer 10 attached to EVA under a solar cell (SC); a heat conductive layer 20 formed on the lower surface of the first resin layer 10; a lower layer formed on the lower surface of the heat conductive layer 20; and an adhesive layer 40 formed between the first resin layer 10 and the heat conductive layer 20.

As illustrated in FIGS. 1 to 4, in the back sheet for a solar cell module for photovoltaic power generation according to the present invention, the first resin layer 10 is configured such that the solar cell (SC) is attached to the upper surface thereof and the heat conductive layer 20 is attached to the lower surface thereof, thus simultaneously transferring heat generated from the solar cell (SC) to the heat conductive layer 20 and forming an insulating layer.

Provided on the upper surface of the first resin layer 10 is the solar cell (SC), and provided on the upper surface of the solar cell (SC) is glass (G). The solar cell (SC) and the glass (G) may be adhered to each other using any one selected from among acryl-, EVA-, and urethane-based adhesives.

The first resin layer 10 is preferably provided in the form of a sheet or a film made of a resin comprising a polymer material, such as PET (PolyEthylene Terephthalate), PI (PolyImide), BOPP (Bi-axially Oriented PolyPropylene), OPP, PVF (PolyVinyl Fluoride), PVDF (PolyVinylidene Fluoride), TPE (Thermo Plastic Elastomer), ETFE (Ethylene Tetrafluoro Ethylene) and an aramid film, having insulation performance and heat dissipation performance.

In particular, the sheet comprising such a polymer material has a superior withstanding voltage and thus there is no concern about breaking an insulation portion, thus enhancing durability. Thereby, such properties enable the products to be variously applicable in various fields requiring a higher withstanding voltage in terms of quality standards.

Also, the first resin layer 10 has high heat resistance thus preventing the insulating layer from breaking or fracturing, and is provided in the form of a thin film, and thereby the solar cell module may become compactly thinned.

As illustrated in FIGS. 1 to 4, in the back sheet for a solar cell module for photovoltaic power generation according to the present invention, the heat conductive layer 20 is connected to the lower surface of the first resin layer 10 so as to transfer heat generated from the solar cell (SC) and to enable thinness of the solar cell module.

The heat conductive layer 20 according to the present invention is preferably made of aluminum, copper, brass, a steel plate, stainless steel, etc., each of which has high heat conductivity, or other materials having heat conductivity equal to or higher than that thereof. Furthermore, these materials have rigidity at a predetermined level or more and high heat resistance, thus preventing deformation of the material due to heat stress, thereby increasing reliability of products.

As illustrated in FIGS. 1 to 4, in the back sheet for a solar cell module for photovoltaic power generation according to the present invention, the lower layer may be a heat conductive coating layer 50 formed using an inorganic coating or an organic-inorganic hybrid coating, or may be a second resin layer 30 in the form of a sheet or a film.

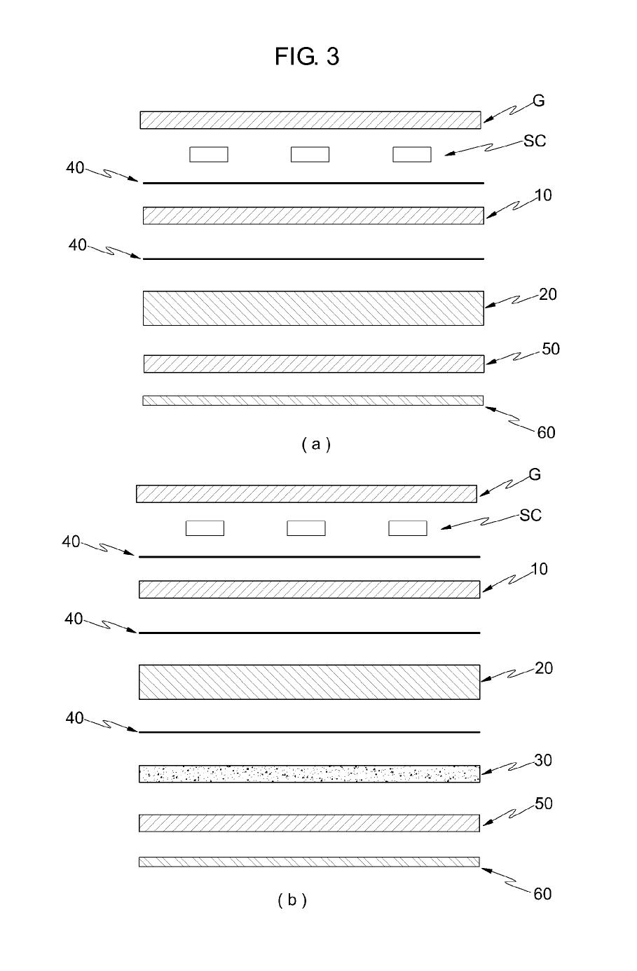

In the case where the heat conductive coating layer 50 is introduced as the lower layer, as illustrated in FIGS. 1 and 3(a), it is disposed on the lower surface of the heat conductive layer 20. The heat conductive coating layer 50 guarantees insulation performance and heat dissipation performance of the solar cell module, increases heat resistance and adhesive strength, and enables thinness of the solar cell module.

The heat conductive coating layer 50 is formed by applying an inorganic coating or an organic-inorganic hybrid coating onto the lower surface of the heat conductive layer 20. This is intended to solve problems caused by forming the heat conductive coating layer using an organic polymer material, that is, problems in which mechanical strength and adhesion are decreased due to low surface energy and low molecular force of the organic polymer material.

The heat conductive coating layer 50 is formed using an inorganic coating including metal oxide, such as ceramic-based alumina, titanium oxide or zirconia, CNT, silicon, etc. As such, the inorganic coating is superior in heat resistance, chemical stability, heat conductivity and insulatability.

However, the use of the inorganic coating is disadvantageous because brittleness is high and thus it is difficult to form a thin film and low-temperature burning cannot be performed. As an alternative thereto, the organic-inorganic hybrid coating obtained by mixing the inorganic coating with an organic material, for example, an organic chemical coating agent such as urethane or polyester, acryl, etc., may be used.

Accordingly, the heat conductive coating layer 50 composed of the organic-inorganic hybrid coating may exhibit superior insulation performance and heat dissipation performance and high heat resistance and adhesive strength.

Furthermore, this layer enables thinness of the module, thus ensuring reliability of products and improving quality of products.

The heat conductive coating layer may be formed using, as an alternative to the inorganic coating or the organic-inorganic hybrid coating, at least one ceramic material selected from among Al₂O₃, AlS, AlN, ZnO₂, TiO₂, SiO₂, TEOS, MTMS, ZrO₃ and MOS₂, thus ensuring insulation performance and heat dissipation performance.

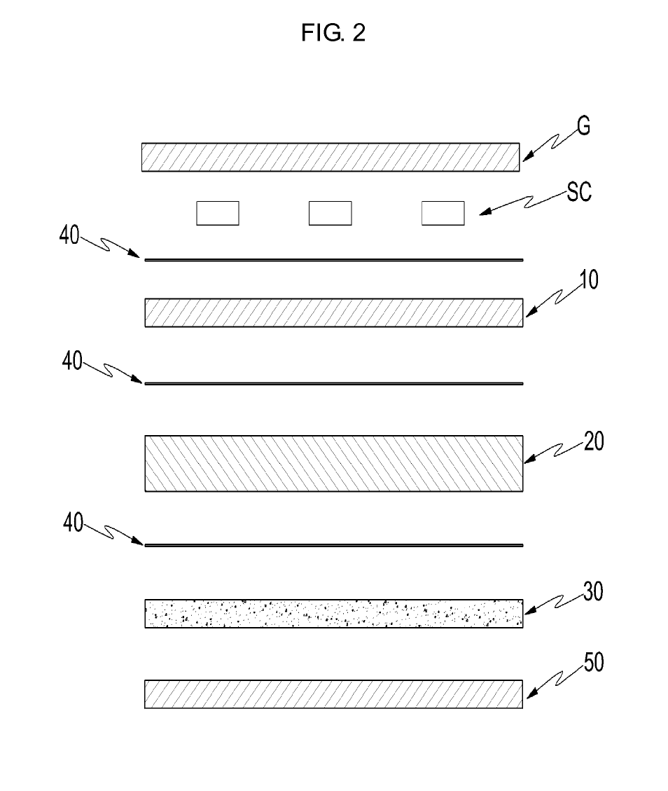

On the other hand, in the case where the second resin layer 30 is introduced as the lower layer according to the present invention, as illustrated in FIGS. 2 and 3(b), it is disposed on the lower surface of the heat conductive layer 20, so that the insulation thickness of the solar cell module is maintained at a predetermined level or more to thus improve insulation performance and increase a withstanding voltage.

The second resin layer 30 is provided in the form of a sheet or film using a polymer material such as PET, PI, BOPP, OPP, PVF, PVDF, TPE, ETFE and an aramid film, thus achieving the above purposes.

Also, as illustrated in FIGS. 2 and 3(b), the heat conductive coating layer 50 is provided on the lower surface of the second resin layer 30. The heat conductive coating layer 50 is made of an inorganic coating or an organic-inorganic hybrid coating, thus obtaining the same functions and effects as in the foregoing.

As illustrated in FIGS. 1 to 4, in the back sheet for a solar cell module for photovoltaic power generation according to the present invention, the adhesive layer 40 includes an EVA-, acryl- or urethane-based clear adhesive film or an adhesive coating, and functions to adhere the first resin layer 10 and the heat conductive layer 20, and also to adhere the heat conductive layer 20 and the second resin layer 30.

Furthermore, the adhesive layer 40 is disposed between the first resin layer 10 and the heat conductive layer 20 to thus adhere the first resin layer 10 and the heat conductive layer 20, and also to adhere the heat conductive layer 20 and the second resin layer 30.

As such, a laminating process using predetermined heat and pressure is performed so that the first resin layer 10, the heat conductive layer 20 and the second resin layer 30 of the solar cell module are adhered to each other by means of the adhesive layer 40.

In this case, as mentioned in the background art, in the case where a laminating process is carried out by applying an adhesive, in particular, a film type adhesive on the upper surface or the upper and lower surfaces of the heat conductive layer in a metal film form, the metal film may undesirably warp due to a difference in cooling rate between the adhesive layer and the metal film in the course of cooling after the laminating process because the adhesive layer has a coefficient of thermal expansion and a cooling rate different from those of the metal material.

Thus, in order to solve the above problem, the first resin layer 10 and the second resin layer 30 are introduced in the present invention, thus preventing the heat conductive layer 20 from warping due to the difference in cooling rate between the adhesive layer 40 and the heat conductive layer 20, thereby maintaining the quality of products. Also, the insulation thickness is sufficiently ensured by virtue of the first resin layer 10 and the second resin layer 30, thereby enhancing insulation performance or a withstanding voltage.

Also, the second resin layer 30 functions to ensure the insulation thickness of the solar cell module. The back sheet comprising the first resin layer 10, the adhesive layer 40, the heat conductive layer 20, the adhesive layer 40 and the second resin layer 30 is formed to a thickness of 250˜750 μm.

As mentioned in the background art, the thickness of the heat dissipation sheet comprising a solar cell, EVA and a metal film is set in the range of about 150˜250 μm. In this case, the heat dissipation sheet may warp or may be easily deformed because of differences in coefficient of thermal expansion and cooling rate between the metal film and the EVA layer directly attached thereto. Also, upon UL certification, the sheet would not pass through a Hi-pot Test, or would not satisfy TUV Partial Discharge Test standards, making it impossible to manufacture actual products.

Hence, in the present invention, the thickness of the back sheet is set in the above range so as to prevent deformation of the back sheet and ensure a sufficient insulation thickness, thereby improving durability and securing reliability of products.

As illustrated in FIGS. 3(a) and 3(b), a protective layer 60 is provided on the lower surface of the heat conductive coating layer 50 according to the present invention. The protective layer 60 is made of ceramic, a fluorine resin, etc. As such, the protective layer 60 has superior weather resistance and corrosion resistance and thus may effectively block UV light and may enhance surface protection, and insulation performance of the solar cell module.

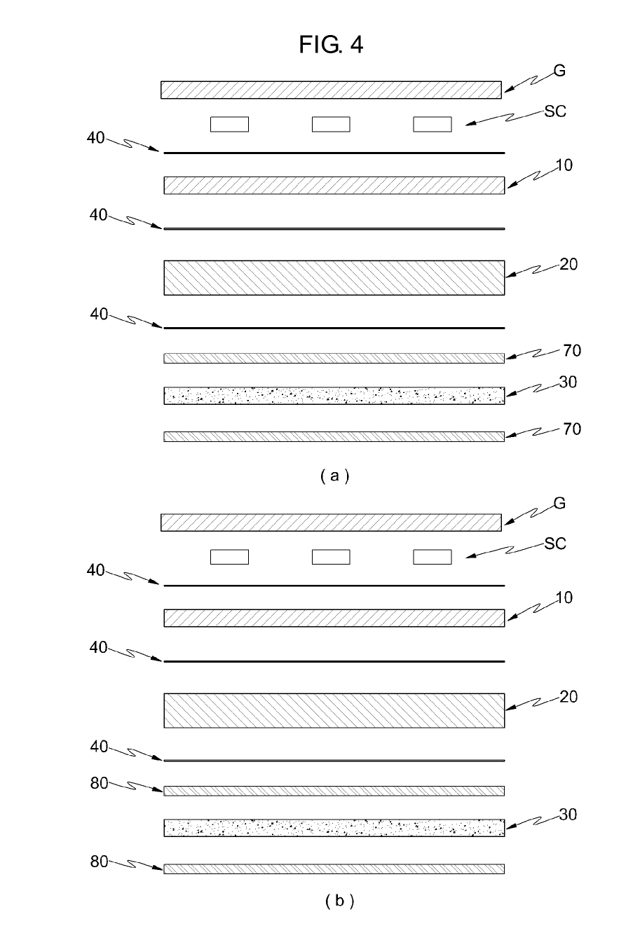

As illustrated in FIG. 4(a), one or both surfaces of the second resin layer 30 according to the present invention are coated with a carbon black resin thus forming a carbon black layer 70 so as to improve heat radiation performance to thereby double heat dissipation efficiency. Such a carbon black layer 70 is superior in heat radiation performance, that is, heat transfer efficiency, and thus may more rapidly emit the conductive heat to air from the second resin layer 30 via the heat conductive layer 20, thus maximizing heat dissipation efficiency.

In the case where the carbon black layer 70 is formed on one surface of the second resin layer 30, in particular, where the carbon black layer 70 is formed on the upper surface of the second resin layer 30, structural stability is attained.

In the case where the carbon black layer 70 is formed on the lower surface of the second resin layer 30 so as to be exposed externally, heat conductivity becomes good, thus further increasing heat dissipation efficiency.

Accordingly, the carbon black layer 70 is preferably applied on the lower surface of the second resin layer 30 so as to be externally exposed, thus contributing to an increase in the heat dissipation efficiency rather than structural stability, ultimately improving heat dissipation performance.

On the other hand, the case where the carbon black layer 70 is formed on both surfaces of the second resin layer 30 may have all the advantages created in the case where the carbon black layer is formed on one surface of the second resin layer 30, and thus becomes possible.

Further, as illustrated in FIG. 4(b), a heat dissipation ceramic coating layer 80 is provided on one or both surfaces of the second resin layer 30. The heat dissipation ceramic coating layer 80 is made of at least one selected from among at least one metal ceramic material selected from the group consisting of alumina, titanium oxide, and zirconia, and at least one non-metal ceramic material selected from the group consisting of organosilane, inorganic silane, a silane coupling agent, and CNT.

Thus, the heat dissipation ceramic coating layer 80 efficiently emits the conductive heat to the outside via the heat conductive layer 20, thereby increasing heat dissipation efficiency and ultimately raising the power generation of the solar cell module.

Although the predetermined shapes and directions of the back sheet for a solar cell module for photovoltaic power generation according to the present invention are mainly described with reference to the appended drawings, those skilled in the art will appreciate that various modifications and variations are possible, without departing from the scope and spirit of the invention as disclosed in the accompanying claims.

1. A back sheet for a solar cell module for photovoltaic power generation, comprising:
a first resin layer attached to EVA under a solar cell;
a heat conductive layer formed on a lower surface of the first resin layer;
a lower layer formed on a lower surface of the heat conductive layer; and
an adhesive layer formed between the first resin layer and the heat conductive layer,
wherein the first resin layer functions to increase a withstanding voltage and to ensure an insulation thickness, thus improving insulation performance.

2. The back sheet of claim 1, wherein the lower layer is a heat conductive coating layer formed using an inorganic coating or an organic-inorganic hybrid coating.

3. The back sheet of claim 2, further comprising a protective layer formed on a lower surface of the heat conductive coating layer to block UV light and to obtain surface protection performance and damp proofing performance.

4. The back sheet of claim 1, wherein the lower layer is a second resin layer,
which further comprises an adhesive layer formed between the heat conductive layer and the second resin layer,
wherein the second resin layer functions to increase a withstanding voltage and to ensure an insulation thickness, thus improving insulation performance, and
either or both of the first resin layer and the second resin layer function to prevent the heat conductive layer from warping due to differences in coefficient of thermal expansion and cooling rate between the adhesive layer and the heat conductive layer.

5. The back sheet of claim 4, further comprising a heat conductive coating layer formed on a lower surface of the second resin layer using an inorganic coating or an organic-inorganic hybrid coating.

6. The back sheet of claim 5, further comprising a protective layer formed on a lower surface of the heat conductive coating layer to block UV light and to obtain surface protection performance and damp proofing performance.

7. The back sheet of claim 1, wherein the first resin layer comprises any one material selected from among PET (PolyEthylene Terephthalate), PI (PolyImide), BOPP (Bi-axially Oriented PolyPropylene), OPP, PVF (PolyVinyl Fluoride), PVDF (PolyVinylidene Fluoride), TPE (Thermo Plastic Elastomer), ETFE (Ethylene Tetrafluoro Ethylene), and an aramid film.

8. The back sheet of claim 1, wherein the heat conductive layer comprises any one metal material selected from among aluminum, copper, brass, a steel plate and stainless steel.

9. The back sheet of claim 1, wherein the adhesive layer is an EVA-, acryl- or urethane-based clear adhesive film.

10. The back sheet of claim 4, wherein the second resin layer comprises any one material selected from among PET, PI, BOPP, OPP, PVF, PVDF, TPE, ETFE and an aramid film.

11. The back sheet of claim 4, wherein the back sheet comprising the first resin layer, the heat conductive layer, the second resin layer and the adhesive layer is formed to a thickness of 250˜750 μm.

12. The back sheet of claim 4, further comprising a carbon black layer formed on one or both surfaces of the second resin layer using a carbon black resin.

13. The back sheet of claim 4, further comprising a heat dissipation ceramic coating layer formed on one or both surfaces of the second resin layer.
